(19) United States
(12) Patent Application Publication
(10) Pub. No.: US 2025/0077740 A1
(43) Pub. Date: Mar. 6, 2025

(54) Artificial Intelligence Simulation of Operating Systems and Command-Line-Interfaces for Operating Systems

(71) Applicant: International Business Machines Corporation, Armonk, NY (US)

(72) Inventors: Jun Su, Beijing (CN); Yang Liang, Beijing (CN); Su Liu, Austin, TX (US); Jennifer Sparks, San Francisco, CA (US)

(21) Appl. No.: 18/242,124

(22) Filed: Sep. 5, 2023

(51) Int. Cl. G06F 30/27; G06F 9/4401

(52) U.S. Cl. CPC G06F 30/27; G06F 9/4406

(57) ABSTRACT

Mechanisms are provided for simulating operating systems. The mechanisms train, for each operating system, a corresponding artificial intelligence (AI) computer model that learns, by way of machine learning training, patterns of input features of inputs to the operating system and corresponding responses from the operating system. A request to simulate a requested operating system is received along with a simulation input whose processing by the requested operating system is to be simulated. An AI computer model corresponding to the requested operating system is executed on the simulation input to simulate processing the simulation input to generate a simulated response. The simulated response is returned as a simulated output of the requested operating system responsive to the input.

### BACKGROUND

The present application relates generally to an improved data processing apparatus and method and more specifically to an improved computing tool and improved computing tool operations/functionality for artificial intelligence simulation of operating systems and command-line interfaces for operating systems.

Command-line interfaces (CLIs) are text-based user interfaces used to run programs, manage computer files and interact with computers. Commands entered into the CLIs are executed by the computer. For example, a CLI may provide a command prompt of the type “c:” and a user may enter a command, such as “\Users\myuser>cd” to “change directory” (cd) and navigate the various folders stored in the storage system. Similarly, a command of the type “c:\>npm install mysoftware” may be used to install a software program “mysoftware” via a software package manager “npm”. Command line interpreters or command line processors are used to interpret and execute the commands entered via the CLI.

CLIs have been available since the 1960s. Various operating systems, such as Linux® (a registered trademark of Linus Torvalds), GNU® (a registered trademark of Free Software Foundation), Microsoft Windows® (a registered trademark of Microsoft Corporation), IBM AIX® (a registered trademark of International Business Machines (IBM) Corporation), Android® (a registered trademark of Google, LLC), iOS® (a registered trademark of Cisco), Solaris, and the like, provide CLIs, however, the commands, and options associated with the various commands, that are recognized by the various CLIs may vary significantly from one operating system CLI to another. That is, the various operating systems have their own command line interpreters or command line processors that recognize different commands and/or options of different commands. As a result, even though a command and/or options of the command may work correctly with one CLI, it may not work correctly with other CLIs.

While CLIs may not be as popular as they once were due to the advent of graphical user interfaces, CLIs still are important tools for software developers, network administrators, system administrators, and information technology (IT) professionals. Web server based operations may be associated with a CLI and many automation tools have to call CLIs for multiple tasks. In fact, some programming and maintenance tasks may not have graphical user interfaces and instead must utilize CLIs. Moreover, in order to receive IT certifications in various technologies, users must demonstrate a proficiency with corresponding CLIs.

### SUMMARY

This Summary is provided to introduce a selection of concepts in a simplified form that are further described herein in the Detailed Description. This Summary is not intended to identify key factors or essential features of the claimed subject matter, nor is it intended to be used to limit the scope of the claimed subject matter.

In one illustrative embodiment, a method, in a data processing system, is provided for simulating operating systems. The method comprises training, for each operating system of one or more operating systems, a corresponding artificial intelligence (AI) computer model that learns, by way of machine learning training, patterns of input features of inputs to the operating system and corresponding responses from the operating system. The method further comprises receiving, from a requestor computing device, a request to simulate a requested operating system, and receiving, from the requestor computing device, a simulation input whose processing by the requested operating system is to be simulated. The method also comprises retrieving an AI computer model corresponding to the requested operating system and executing the retrieved AI computer model on the simulation input to simulate processing, by the request operating system, of the simulation input to generate a simulated response. In addition, the method comprises returning the simulated response to the requestor computing device as a simulated output of the requested operating system responsive to the input.

In other illustrative embodiments, a computer program product comprising a computer useable or readable medium having a computer readable program is provided. The computer readable program, when executed on a computing device, causes the computing device to perform various ones of, and combinations of, the operations outlined above with regard to the method illustrative embodiment.

In yet another illustrative embodiment, a system/apparatus is provided. The system/apparatus may comprise one or more processors and a memory coupled to the one or more processors. The memory may comprise instructions which, when executed by the one or more processors, cause the one or more processors to perform various ones of, and combinations of, the operations outlined above with regard to the method illustrative embodiment.

These and other features and advantages of the present invention will be described in, or will become apparent to those of ordinary skill in the art in view of, the following detailed description of the example embodiments of the present invention.

### BRIEF DESCRIPTION OF THE DRAWINGS

The invention, as well as a preferred mode of use and further objectives and advantages thereof, will best be understood by reference to the following detailed description of illustrative embodiments when read in conjunction with the accompanying drawings, wherein:

FIG. 1 is an example diagram illustrating the differences in operating system supported command line interfaces (CLIs) with regard to an example command of a CLI;

FIG. 2 is an example diagram of a distributed data processing system environment in which aspects of the illustrative embodiments may be implemented and at least some of the computer code involved in performing the inventive methods may be executed;

FIG. 3 is an example diagram of an intelligent command line interface simulation bot (ICSB) framework and system in accordance with one illustrative embodiment;

FIG. 4 is an example flow diagram illustrating an example operation of the ICSB framework and system in accordance with one illustrative embodiment;

FIG. 5 is an example diagram illustrating a simulation of a command in a simulated operating system CLI in accordance with one illustrative embodiment;

FIG. 6 is an example diagram illustrating an example simulated CLI output or result generated based on an input command to the ICSB framework and system in accordance with one illustrative embodiment; and

FIG. 7 is an example diagram of a ICSB data structure over a period of time of a ICSB session in accordance with one illustrative embodiment.

### DETAILED DESCRIPTION

The illustrative embodiments provide an improved computing tool and improved computing tool operations/functionality for artificial intelligence simulation of operating systems and of command-line interfaces (CLIs) for operating systems. For purposes of the following description, simulation of CLIs of operating systems will be used as an example for demonstrating the mechanisms of the illustrative embodiments. However, it should be appreciated that the mechanisms of the illustrative embodiments are not limited to simulation of specifically command line interfaces, but may be implemented to simulate various operations of the operating system. That is, rather than requiring a machine learning of specifically patterns of input features for commands for command line interfaces as a simulation input, the artificial intelligence (AI) computer models of the illustrative embodiments may likewise learn patterns of input features for other types of inputs to the operating system and simulate a corresponding operating system response to such inputs. Thus, the invention is not limited to command line interfaces and simulating processing of command line interface commands and options by a simulated operating system.

As noted above, there are many different operating systems, e.g., Linux® (a registered trademark of Linus Torvalds), GNU® (a registered trademark of Free Software Foundation), Microsoft Windows® (a registered trademark of Microsoft Corporation), IBM AIX® (a registered trademark of International Business Machines (IBM) Corporation), Android® (a registered trademark of Google, LLC), iOS® (a registered trademark of Cisco), Solaris, etc., each having their own CLIs and supported commands and options for those commands. As such, while a user may be proficient with one operating system and CLI, that does not mean that the user will be proficient with other operating systems and CLIs. Moreover, if a user wishes to learn different operating system CLIs, the user would need to set up physical hardware and install/configure each operating system of interest separately in order to learn each operating system's CLI. This requires a significant amount of setup time and configuration which may be difficult for beginning users and those with limited technical knowledge. Moreover, this may be a costly process if one were to attempt to rent cloud servers to provide the operating system environments and corresponding CLIs, with the rented servers often not accurately reflecting real-world operating system environments of the individual users. This is especially problematic for individuals that are attempting to obtain certifications for different information technology who may not have access to the equipment and software to implement the CLIs and do not have the resources to rent cloud based servers running the operating systems to implement the CLIs.

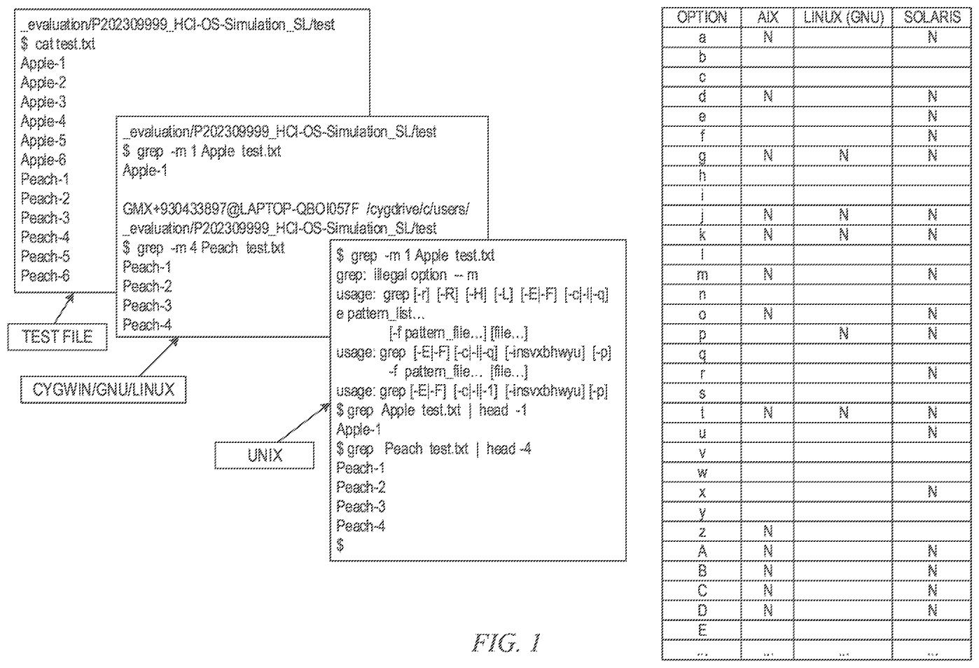

FIG. 1 is an example diagram illustrating the differences in operating system supported CLIs with regard to an example command of a CLI. In the example shown, the “grep” command may be used in multiple different operating systems, e.g., Linux® and AIX®, however not every operating system supports the same options for the “grep” command. The grep command is used to search a file for a particular pattern of characters and displays all lines that contain that pattern, e.g., “grep Apple test.txt” will display all lines of the file “test.txt” that have the character pattern “Apple”. Many CLI commands may make use of options that set forth further criteria, filters, or controls on the commands, and different CLIs may enabled different ones of these options. In the depicted example, the option “-m” is utilized, which in the Linux® operating system is used to specify a maximum number of results returned, e.g., an option of “-m 4” indicates that the first 4 results are returned from the search.

As shown in FIG. 1, the “-m” option is only defined in the Linux® operating system's command line interpreter and is not defined in the AIX® operating system's command line interpreter. Instead, if one wants to achieve a similar result in AIX® for the Linux® command “grep -m 4 Peach test.txt”, one must execute the command “grep Peach test.txt|head-4”. If one wants to identify such a difference between the CLIs, such as for educational purposes, certification, or the like, one would have to find and install two different operating systems, i.e., Linux® and AIX®, and then run the “grep -m 4 Peach test.txt” command with the option “-m” in both operating system command line interfaces to demonstrate that the AIX® operating system does not support such an option, and then determine what other command and options would achieve a similar result through manual effort.

The illustrative embodiments provide mechanisms for simulating operating systems, and in some illustrative embodiments, the command line interfaces (CLIs) of the operating systems by implementing machine learning trained artificial intelligence computer models that learn operating system and/or CLI responses to patterns of input features. In this way, the mechanisms of the illustrative embodiments may simulate various operating systems and/or CLIs without the user having to have access to all the resources needed to implement the operating system and/or CLI on a computing device. Moreover, the illustrative embodiments facilitate comparisons of operating systems and/or CLIs with regard to their operation on given inputs, again without having to have access to the actual software and hardware resources that would be needed to execute instances of operating systems and their CLIs on computing devices.

The following description provide examples of embodiments of the present invention, and variations and substitutions may be made in other embodiments. Several examples will now be provided to further clarify various aspects of the present disclosure.

Example 1: A method, in a data processing system, is provided for simulating operating systems. The method comprises training, for each operating system of one or more operating systems, a corresponding artificial intelligence (AI) computer model that learns, by way of machine learning training, patterns of input features of inputs to the operating system and corresponding responses from the operating system. The method further comprises receiving, from a requestor computing device, a request to simulate a requested operating system, and receiving, from the requestor computing device, a simulation input whose processing by the requested operating system is to be simulated. The method also comprises retrieving an AI computer model corresponding to the requested operating system and executing the retrieved AI computer model on the simulation input to simulate processing, by the request operating system, of the simulation input to generate a simulated response. In addition, the method comprises returning the simulated response to the requestor computing device as a simulated output of the requested operating system responsive to the input.

The above limitations advantageously enable the simulation of an operating system without having to have a specific computing environment and operating system resources, i.e., libraries, operating system memory and processor resources, etc. Rather, the operating system is simulated by AI computer models. This enhances recognition of operating system performance differences between operating systems with regard to similar inputs and permits more efficient evaluation of operating system performance by simulating operating system responses rather than having to install and configure operating systems on various computing devices with potentially different environmental configurations.

Example 2: The limitations of any of Examples 1 and 3-11, where the corresponding AI computer model is a command line interface (CLI) computer model that maps patterns of input features of commands input to a CLI of the operating system with corresponding CLI responses. In some illustrative embodiments, the request is a request to simulate a CLI of the requested operating system and wherein the input whose processing by the requested operating system is to be simulated is a command to the CLI. Thus, these above limitations advantageously enable the AI computer model to simulate the responsive outputs of a command line interface of an operating system for input commands, again without requiring the specific computing environment and operating system resources for implementing the actual operating system and command line interface. Rather, the command line interface is simulated by AI computer models. Thus, a user can specify what operating system for which they wish to simulate the command line interface and specify the command that they wish to simulate, and the AI computer model will simulate the command line interface that would be presented without having to actually execute the operating system and the command line interface. This facilitates simulation of operating systems and command line interfaces through an AI chat or conversational bot.

Example 3: The limitations of any of Examples 1-2 and 4-11, where the simulation input is a command for a command line interface (CLI) of the requested operating system, and the simulated output is a simulated CLI response generated by simulating the requested operating system based on the retrieved AI computer model. These above limitations advantageously enable the AI computer model to simulate the responsive outputs of a command line interface of an operating system for input commands. The command line interface is simulated by AI computer models. Thus, a user can specify what operating system for which they wish to simulate the command line interface and specify the command that they wish to simulate, and the AI computer model will simulate the command line interface that would be presented without having to actually execute the operating system and the command line interface. This facilitates improved learning of operating systems and command line interfaces as one can quickly switch between operating systems and command line interfaces to see how each would respond to a given command and how they differ in their responses. For example, one may determine which operating systems support particular commands and options and which do not. In some cases, a side-by-side comparison of operating system and command line interface responses may be provided that facilitates such learning.

Example 4: The limitations of any of Examples 1-3 and 5-11, where returning the simulated response to the requestor computing device as a simulated output of the requested operating system responsive to the input comprises returning the simulated CLI response in a simulated user interface mimicking a command line interface of the requested operating system. Thus, the requestor can operate as if interfacing with a CLI, but the CLI is simulated via AI computer models. Thus, the requestor need not have access to specific hardware and software resources for implementing actual operating systems and corresponding CLIs yet still be able to obtain results that simulate the actual operation of the operating system and CLIs.

Example 5: The limitations of any of Examples 1-4 and 6-11 where the patterns of input features comprise patterns of operating system commands input to a command line interface of the operating system, and corresponding options for those operating system commands. Thus, a requestor can simulate various operating systems and command line interfaces for various combinations of commands and options to determine how the various operating systems respond to the commands/options. In some cases, options may not be supported by all operating systems and by simulating the responses by operating systems and command line interfaces, one can quickly identify the differences in operating system and command line interface operations with regard to these options without having to install and reconfigure computing devices to execute the various operating systems and command line interfaces.

Example 6: The limitations of any of Examples 1-5 and 7-11, where the one or more operating systems comprises a plurality of operating systems, training the AI computer model comprises training a separate AI computer model for each different operating system in the plurality of operating systems, and each of the AI computer models are trained to simulate a same set of command line interface commands but with regard to a corresponding operating system, in the plurality of operating systems. Thus, a requestor can simulate various operating systems and command line interfaces for various combinations of commands and options to determine how the various operating systems respond to the same commands/options for educational and development purposes. That is, one can determine what commands and options are supported by the various operating systems and command line interfaces and can develop software based on this knowledge. Moreover, for user certifications, it may be required that a user have familiarity with various operating systems and their command line interfaces, and the AI computer model based simulation of the operating systems and command line interfaces facilitates comparison of multiple operating systems in a quick and efficient way without having to actually configure a computing system to execute the operating system with all of its configured resources.

Example 7: The limitations of any of Examples 1-6 and 8-11, where the AI computer model is trained based on a machine learning processing of a training data set comprising a set of command line interface commands, options for the command line interface commands, and expected command line interface outputs for the commands and options based on an ingested corpus of source documents comprising operating system design documents, support hubs, and man pages. In this way, the AI computer models learn from the corpus how various operating systems and command line interfaces process and respond to various commands and options from natural language and/or structured documents and information sources. These limitations advantageously configure the AI mechanisms of the illustrative embodiments to specifically simulate how particular operating systems respond to specific inputs and how command line interfaces of operating systems handle such inputs so as to provide an accurate simulated response. This again enhances the way in which the operating systems and command line interfaces are simulated and facilitate better understanding of operating system and command line interface performance.

Example 8: The limitations of any of Examples 1-7 and 9-11 where the request is a natural language request submitted via a chatbot interface and specifies the requested operating system and the simulating input whose processing by the requested operating system is to be simulated. Thus, a user can submit a natural language request to simulate an operating system and/or command line interface through a conversation with a chatbot and the request may be processed, and the operating system/command line interface may be simulated on the user's natural language request. This facilitates a better user experience and does not require the user to have access to an actual instance of the operating system and/or command line interface. That is, the user can simply input a natural language input requesting simulation of a particular operating system and/or command line interface and specify the command that they wish to simulate, and the AI computer model based system will respond with a simulated response as if the command were processed by an actual operating system and/or command line interface.

Example 9: The limitations of any of Examples 1-8 and 10-11, where a user profile is received that specifies a subset of operating systems to simulate, wherein the training of the corresponding AI computer model is performed for each of the operating systems specified in the user profile. In this way, the user may specify which operating systems they want to simulate, and a different AI computer model may be trained for each of the operating systems that the user wishes to simulate. Moreover, these limitations advantageously allow the user to customize the AI computer model based simulation of operating systems and/or command line interfaces to their specific needs, i.e., to the operating systems, command line interfaces, and commands that they wish to simulate. This allows each user to have their own customized configuration of AI computer models and simulated operating systems and/or command line interfaces.

Example 10: The limitations of any of Examples 1-9 and 11, where the user profile further specifies, for the subset of operating systems, a scope of commands that are to be learned by the training of the corresponding AI computer models, and a default set of environment variables to use in simulating the subset of operating systems. In this way, the user can specify what types of commands they want to simulate and can specify what environment variables to use to simulate the commands. Thus, a user can customize the simulation to the particular computing environment with which they expect to operate. This advantageously provides an ability to simulate different computing environments and different commands without having to have access to those different computing environments and without having to have access to actual instances of operating systems and command line interfaces in those computing environments.

Example 11: The limitations of any of Examples 1-10, where user feedback information is received in response to the simulated response indicating whether the simulated response is correct or incorrect, and the training of the retrieved AI computer model is updated based on the user feedback information. Thus, the user can inform the system whether the training is correct or needs to be modified via the user feedback information and this information may be used to make the training of the AI computer model more accurate to what the user expects from the operating system responses and/or command line interface responses. This advantageously allows for continuous training of the AI computer model to improve its performance and the simulated results generated by the AI computer model.

Example 12: A system comprising one or more processor and one or more computer-readable storage media collectively storing program instructions which, when executed by the one or more processors, are configured to cause the one or more processors to perform a method according to any one of Examples 1-11. The above limitations advantageously enable a system comprising one or more processors to perform and realize the advantages described with respect to Examples 1-11.

Example 13: A computer program product comprising one or more computer readable storage media, and program instructions collectively stored on the one or more computer readable storage media, the program instructions comprising instructions configured to cause one or more processors to perform a method according to any one of Examples 1-11. The above limitations advantageously enable a computer program product having program instructions configured to cause one or more processors to perform and realize the advantages described with respect to Examples 1-11.

Example 14: A computer-implemented method, system, or computer program product for simulating one or more operating systems. The method, system or computer program product comprises training, for each operating system of one or more operating systems, a corresponding artificial intelligence (AI) computer model that learns, by way of machine learning training, patterns of input features of inputs to the operating system and corresponding responses from the operating system. The method, system, or computer program product further comprises receiving, from a requestor computing device, a request to simulate a requested operating system. The method, system, or computer program product also comprises receiving, from the requestor computing device, a simulation input whose processing by the requested operating system is to be simulated. The method, system, or computer program product comprises retrieving an AI computer model corresponding to the requested operating system. In addition, the method, system, or computer program product comprises executing the retrieved AI computer model on the simulation input to simulate processing, by the request operating system, of the simulation input to generate a simulated response. Moreover, the method, system, or computer program product returning the simulated response to the requestor computing device as a simulated output of the requested operating system responsive to the input.

Additionally, the method, system, or computer program product comprises the simulation input being a command for a command line interface (CLI) of the requested operating system, and wherein the simulated output is a simulated CLI response generated by simulating the requested operating system based on the retrieved AI computer model. Furthermore, the method, system, or computer program product comprises returning the simulated response to the requestor computing device as a simulated output of the requested operating system responsive to the input at least by returning the simulated CLI response in a simulated user interface mimicking a command line interface of the requested operating system.

The above example advantageously realizes the benefits described with respect to Examples 1, 3, and 4. Thus, for example, a user can access an interface that simulates an operating system command line interface without having to install and configure an operating system. Instead the user may request simulation of a particular operating system and be presented with a simulated command line interface. The user can specify the command that they wish to have simulated and the AI computer model(s) simulate the command line interface response to the command, presenting it in the simulated command line interface. All of this may be done without having to actually implement the requested operating system, as it is performed using AI computer models which have learned the way in which different operating systems respond to command line interface commands and options.

As can be seen from the above, the illustrative embodiments provide an improved computing tool and improved computing tool operations/functionality that learns, through machine learning processes, a set of CLIs and simulates the learned CLIs such that the simulated CLIs can dynamically respond to user input based on a knowledge base of command line responses and machine learning of patterns of CLI commands associated with the command line responses. Thus, users are able to design, learn, and practice CLIs under a user preferred virtualized operating system without having to set up physical hardware and install/configure an actual operating system and without having to expend resources renting cloud servers or other hardware that provide the operating system and CLIs of interest. The illustrative embodiments may serve to provide simulation of CLIs that aid training and education of users, such as for information technology (IT) certifications and the like. Moreover, the illustrative embodiments provide simulated CLIs such that a user can dynamically switch between different simulated CLIs on-the-fly or have multiple different simulated CLIs presented at substantially a same time so as to perceive the differences in the way that different CLIs handle the same command.

With the mechanisms of the illustrative embodiments, a framework and system is defined to support simulation of operating systems, and in particular an Intelligent Command Line Interface (CLI) Simulation Bot (ICSB) and corresponding operations/functionality. The framework and system comprises a plurality of different components including an ICSB server that operates to provide simulated CLIs to ICSB clients, where the ICSB server further includes an ICSB manager that manages the various ICSB data structures, ICSB criteria and user profiles, ICSB learner that learns patterns of command and option inputs to a CLI and the corresponding responses from the CLI, ICSB parser that operates to parse a command input by a ICSB client and simulate the CLI based on the command input, and ICSB adjuster that operates to update the machine learning of the CLI based on user feedback. The operations of these components will be described in greater detail hereafter.

In addition, a ICSB data structure is defined to handle ICSB operations, where this ICSB data structure is updated over time to include information representing the user's simulation of one or more CLIs of one or more operating systems. In accordance with some illustrative embodiments, the ICSB data structure comprises user, operating system (OS) and CLI feature data including user identifier (UserID), operating system name (OSName), configuration information for the operating system and user identifier (Configuration[OSName][UserID]), CLI list of operating systems invoked by the user (CLIList[OSName]), a CLI log for the operating system and user identifier (CLILog[OSName][UserID]) which maintains a log for each operating system as to the commands entered by the user corresponding to the user ID, a user command (UserCMD) specifying the latest command entered by the user into the simulated CLI, a command options (CMDOptions) specifying the latest command options entered by the user into the simulated CLI, a command output generated by the simulated CLI for the latest entered command (CMDOutput), and an error state (Error State) specifying whether or not an error occurred in the CLI when processing the entered command, e.g., the CLI does not support a particular command or option. These features in the ICSB data structure are populated and updated over time as a user interacts with the ICSB server via their ICSB client, such that some features may not be populated during a first time interval but may be populated and updated over time during subsequent time intervals, as will be described in greater detail hereafter. Thus, the ICSB data structure is a dynamic data structure that is populated and updated based on user inputs via the ICSB client and results of the CLI simulations performed during a user session with the ICSB server.

The framework and system operates to allow users to configure and customize ICSB criteria, e.g., supported operating systems, scope of CLI, i.e., how many and what commands and options to include in the simulated CLI, default environment variables (e.g., locale (e.g., spoken language of user), IP address, CPU/GPU/Memory, storage type and size, available computing tools, etc.), and the like. The ICSB manager mentioned above, may operate to provide an interface through which such configuration and customization may be performed, and may manage and maintain an ICSB profile comprising the ICSB data structure for a client session between the user's ICSB client computing device and the ICSB server, as well as a history of such ICSB data structures if desired, and the ICSB criteria. User profiles may be defined and maintained by the ICSB manager for each of the users where such user profiles may specify information about particular operating systems that the user wishes to simulate via the ICSB server, what subset of commands and options the user is wanting to simulate, as well as CLI simulation history information which may be used and/or viewed for educational, training, and certification purposes, for example.

The ICSB learner of the ICSB framework and system learns, through machine learning operations, a set of CLI commands, options, and expected outputs under each of a plurality of operating systems. The machine learning operations may be performed based on knowledge acquired from a corpus comprising a variety of sources and documents (e.g., Red Books, support hubs, websites (e.g., Wikipedia and the like), man pages, design documents, etc. The ICSB learner ingests the corpus comprising the various sources of operating system CLI information, which may include structured or unstructured data, and learns patterns of CLI commands/options with corresponding CLI responses or outputs. For example, if the ICSB criteria specifies a command of the type “grep” is to be learned from Linux® user documents, Wikipedia, man page, design documents, etc., then the ICSB learner learns an association between “grep” and corresponding CLI outputs, e.g., if the grep command is entered, then the CLI responds with lines of a file that have textual patterns matching the character string specified in the grep command. Hence, patterns of inputs are correlated with patterns of outputs.

The ICSB client computing device may be configured to execute an ICSB monitor that monitors for user requests to simulate operating systems and/or CLIs of operating systems. The ICSB monitor may receive a user request, via a user interface, to simulate a specified operating system and/or CLI and may send the user request to the ICSB server. The ICSB server may present an interface through which requests may be submitted by the ICSB monitor. For example, the ICSB server and ICSB monitor may present a chatbot type interface, or other natural language interface, through which the user may submit natural language requests, such as “Simulate CLI for AIX® grep instruction with -m option”, or the like. A ICSB parser of the ICSB server may parse the request, and via a ICSB extractor, extract various key elements of the request including the User ID, operating system name, command name, correlated options, and the like. In so doing, the ICSB extractor and ICSB parser are able to identify the ICSB identifier for the requested operating system and command which is then sent to an operating system simulation agent implementing a CLI simulated based on the learned associations of input command patterns and output or response patterns from the ICSB learner. The operating system simulation agent mimics the user specified operating system according to a ICSB profile, user profile, and ICSB criteria dynamically or “on-the-fly” and executes the CLI simulator to simulate the CLI response to the specified command with correlated options. In this way, the CLI simulator generates a mapped expected output or response to the user specified command for the user specified operating system CLI.

A ICSB rendering engine executing on the client computing device as part of the ICSB client presents the expected output or response in a simulated user command output. The ICSB rendering engine may further simulate a CLI such that the user may enter a command via the simulated CLI, and this command may be converted to a request sent to the ICSB server which is then processed as discussed above to simulate the CLI based on the learned correlations between patterns of CLI commands/options and patterns of CLI outputs. Similarly, the results of the simulation may be presented to the requestor as a simulated user interface mimicking the command line interface of the operating system.

It should be appreciated that this simulation of the CLI may return outputs or results that the user does not believe represent an actual correct CLI response in the user's computing environment. The ICSB rendering engine may provide user interface elements through which a user may specify whether the returned CLI output or result is correct or not according to the user's understanding and provide feedback as to what the user's expected result is for the entered command and options. This user feedback may be provided to the ICSB server which sends the user feedback to the ICSB adjuster that adjusts the machine learning model that maps patterns of input commands and options with CLI output or results, so as to update the machine learning model to correct for any discrepancies between what the machine learning model based simulation of the CLI generates and what the users expect to see as a correct CLI response to an entered command and options.

Thus, the illustrative embodiments provide an improved computing tool and improved computing tool operations/functionality that are specifically directed to simulating command line interfaces of operating systems through machine learning of command line interface responses to command and option inputs. The illustrative embodiments automatically learn associations of patterns in input commands and options for various operating system command line interfaces with patterns of command line interface responses or outputs. This mapping of patterns then represents, for each operating system command line interface, a command line interface (CLI) mode which may be maintained in a CLI model repository. The CLI models of the CLI model repository may then be dynamically applied to requests from users to simulate the CLI of a specified operating system for a specified command and options and thereby generate a simulated CLI response or output. All of this is done without having to actually install the operating system and configure it for a particular computer execution environment.

The ICSB framework and system of the illustrative embodiments provides a cost effective solution to tasks that require different operating system command line interfaces to accomplish, such as educational, training, and certification tasks. That is, by simulating and virtualizing operating system command line interfaces, the illustrative embodiments can significantly reduce the cost of hardware and software needed for these tasks.

In addition, the ICSB framework and system of the illustrative embodiments promotes accessibility of various operating system command line interfaces. That is, the virtualized operating system command lines can be accessed from anywhere with a data network connection, e.g., Internet connection, as the ICSB framework and system may be provided as a service via one or more cloud computing systems, server computing systems, or the like. This makes it significantly easier for individuals and organizations to access the simulation of CLIs to perform their educational, training, and certification tasks as well as any other tasks that may require CLI access.

The ICSB framework and system of the illustrative embodiments is customizable as the virtualized operating system command line interface can be modified to meet specific needs and requirements. That is, users may dynamically select operating system command line interfaces as desired and switch between them “on-the-fly” as the user needs. This allows for a more tailored learning experience, as the ICSB framework and system is dynamically responsive to user requests without requiring long wait periods for the installation and configuration of different operating systems and their command line interfaces.

The ICSB framework and system of the illustrative embodiments provides a safe and secure environment for users to experiment and learn without the risk of damaging physical hardware or important data. The ICSB framework and system of the illustrative embodiments can easily scale to accommodate multiple users and different operating systems, as the ICSB framework and system can learn CLI patterns and mappings between patterns of inputs and outputs to the CLI for operating systems as requested. This allows the ICSB framework and system to be a significant educational, training, certification, and experimentation tool for large organizations.

The ICSB framework and system can be integrated into various cloud computing system offerings, such as IBM Cloud, to provide users with virtualized operating system command line interfaces on-demand, which is a cost-effective and scalable solution for organizations that need to run different operating systems for their applications. The ICSB framework and system can be used in the development and testing of artificial intelligence (AI) models, e.g., IBM Watson, and applications that require different operating systems and configurations, which can improve the accuracy and reliability of these models. The ICSB framework and system can be used to simulate and test different cybersecurity threats and vulnerabilities, such as via IBM Security, which can help organizations improve their security measures and protect against cyber-attacks. The ICSB framework and system can be used by researchers to experiment with different operating systems and configurations, such as via IBM Research, which can lead to the development of new technologies and innovations.

Before continuing the discussion of the various aspects of the illustrative embodiments and the improved computer operations performed by the illustrative embodiments, it should first be appreciated that throughout this description the term “mechanism” will be used to refer to elements of the present invention that perform various operations, functions, and the like. A “mechanism,” as the term is used herein, may be an implementation of the functions or aspects of the illustrative embodiments in the form of an apparatus, a procedure, or a computer program product. In the case of a procedure, the procedure is implemented by one or more devices, apparatus, computers, data processing systems, or the like. In the case of a computer program product, the logic represented by computer code or instructions embodied in or on the computer program product is executed by one or more hardware devices in order to implement the functionality or perform the operations associated with the specific “mechanism.” Thus, the mechanisms described herein may be implemented as specialized hardware, software executing on hardware to thereby configure the hardware to implement the specialized functionality of the present invention which the hardware would not otherwise be able to perform, software instructions stored on a medium such that the instructions are readily executable by hardware to thereby specifically configure the hardware to perform the recited functionality and specific computer operations described herein, a procedure or method for executing the functions, or a combination of any of the above.

The present description and claims may make use of the terms “a”, “at least one of”, and “one or more of” with regard to particular features and elements of the illustrative embodiments. It should be appreciated that these terms and phrases are intended to state that there is at least one of the particular feature or element present in the particular illustrative embodiment, but that more than one can also be present. That is, these terms/phrases are not intended to limit the description or claims to a single feature/element being present or require that a plurality of such features/elements be present. To the contrary, these terms/phrases only require at least a single feature/element with the possibility of a plurality of such features/elements being within the scope of the description and claims.

Moreover, it should be appreciated that the use of the term “engine,” if used herein with regard to describing embodiments and features of the invention, is not intended to be limiting of any particular technological implementation for accomplishing and/or performing the actions, steps, processes, etc., attributable to and/or performed by the engine, but is limited in that the “engine” is implemented in computer technology and its actions, steps, processes, etc. are not performed as mental processes or performed through manual effort, even if the engine may work in conjunction with manual input or may provide output intended for manual or mental consumption. The engine is implemented as one or more of software executing on hardware, dedicated hardware, and/or firmware, or any combination thereof, that is specifically configured to perform the specified functions. The hardware may include, but is not limited to, use of a processor in combination with appropriate software loaded or stored in a machine readable memory and executed by the processor to thereby specifically configure the processor for a specialized purpose that comprises one or more of the functions of one or more embodiments of the present invention. Further, any name associated with a particular engine is, unless otherwise specified, for purposes of convenience of reference and not intended to be limiting to a specific implementation. Additionally, any functionality attributed to an engine may be equally performed by multiple engines, incorporated into and/or combined with the functionality of another engine of the same or different type, or distributed across one or more engines of various configurations.

In addition, it should be appreciated that the following description uses a plurality of various examples for various elements of the illustrative embodiments to further illustrate example implementations of the illustrative embodiments and to aid in the understanding of the mechanisms of the illustrative embodiments. These examples intended to be non-limiting and are not exhaustive of the various possibilities for implementing the mechanisms of the illustrative embodiments. It will be apparent to those of ordinary skill in the art in view of the present description that there are many other alternative implementations for these various elements that may be utilized in addition to, or in replacement of, the examples provided herein without departing from the spirit and scope of the present invention.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

It should be appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination.

The present invention may be a specifically configured computing system, configured with hardware and/or software that is itself specifically configured to implement the particular mechanisms and functionality described herein, a method implemented by the specifically configured computing system, and/or a computer program product comprising software logic that is loaded into a computing system to specifically configure the computing system to implement the mechanisms and functionality described herein. Whether recited as a system, method, of computer program product, it should be appreciated that the illustrative embodiments described herein are specifically directed to an improved computing tool and the methodology implemented by this improved computing tool. In particular, the improved computing tool of the illustrative embodiments specifically provides an intelligent command line interface simulation bot. The improved computing tool implements mechanism and functionality, such as machine learning of command and option patterns with CSI output or responses, simulation of CSIs for various operating systems, and processing command inputs from users via such simulations to generate simulated responses or outputs without having to install and configure the corresponding operating system. These operations cannot be practically performed by human beings either outside of, or with the assistance of, a technical environment, such as a mental process or the like. The improved computing tool provides a practical application of the methodology at least in that the improved computing tool is able to simulate to users command line interfaces of various operating systems dynamically for educational, training, and certification purposes, for example.

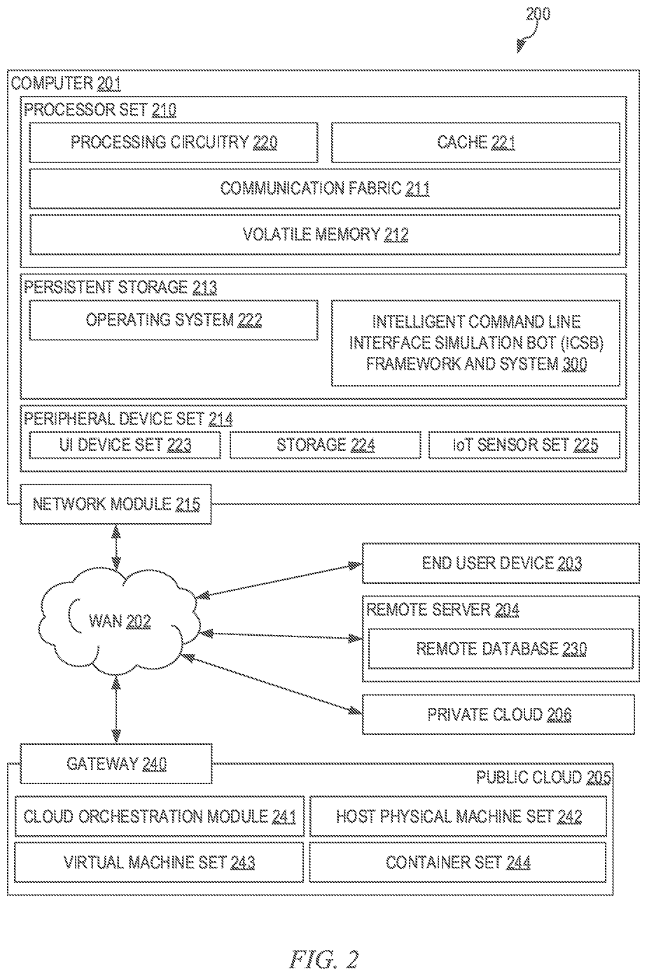

FIG. 2 is an example diagram of a distributed data processing system environment in which aspects of the illustrative embodiments may be implemented and at least some of the computer code involved in performing the inventive methods may be executed. That is, computing environment 200 contains an example of an environment for the execution of at least some of the computer code involved in performing the inventive methods, such as intelligent command line interface simulation bot (ICSB) framework and system 300. In addition, ICSB framework and system 300, computing environment 200 includes, for example, computer 201, wide area network (WAN) 202, end user device (EUD) 203, remote server 204, public cloud 205, and private cloud 206. In this embodiment, computer 201 includes processor set 210 (including processing circuitry 220 and cache 221), communication fabric 211, volatile memory 212, persistent storage 213 (including operating system 222 and ICSB framework and system 300, as identified above), peripheral device set 214 (including user interface (UI), device set 223, storage 224, and Internet of Things (IoT) sensor set 225), and network module 215. Remote server 204 includes remote database 230. Public cloud 205 includes gateway 240, cloud orchestration module 241, host physical machine set 242, virtual machine set 243, and container set 244.

Computer 201 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 230. As is well understood in the art of computer technology, and depending upon the technology, performance of a computer-implemented method may be distributed among multiple computers and/or between multiple locations. On the other hand, in this presentation of computing environment 200, detailed discussion is focused on a single computer, specifically computer 201, to keep the presentation as simple as possible. Computer 201 may be located in a cloud, even though it is not shown in a cloud in FIG. 2. On the other hand, computer 201 is not required to be in a cloud except to any extent as may be affirmatively indicated.

Processor set 210 includes one, or more, computer processors of any type now known or to be developed in the future. Processing circuitry 220 may be distributed over multiple packages, for example, multiple, coordinated integrated circuit chips. Processing circuitry 220 may implement multiple processor threads and/or multiple processor cores. Cache 221 is memory that is located in the processor chip package(s) and is typically used for data or code that should be available for rapid access by the threads or cores running on processor set 210. Cache memories are typically organized into multiple levels depending upon relative proximity to the processing circuitry. Alternatively, some, or all, of the cache for the processor set may be located “off chip.” In some computing environments, processor set 210 may be designed for working with qubits and performing quantum computing.

Computer readable program instructions are typically loaded onto computer 201 to cause a series of operational steps to be performed by processor set 210 of computer 201 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 221 and the other storage media discussed below. The program instructions, and associated data, are accessed by processor set 210 to control and direct performance of the inventive methods. In computing environment 200, at least some of the instructions for performing the inventive methods may be stored in ICSB framework and system 300 in persistent storage 213.

Communication fabric 211 is the signal conduction paths that allow the various components of computer 201 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 212 is any type of volatile memory now known or to be developed in the future. Examples include dynamic type random access memory (RAM) or static type RAM. Typically, the volatile memory is characterized by random access, but this is not required unless affirmatively indicated. In computer 201, the volatile memory 212 is located in a single package and is internal to computer 201, but, alternatively or additionally, the volatile memory may be distributed over multiple packages and/or located externally with respect to computer 201.

Persistent storage 213 is any form of non-volatile storage for computers that is now known or to be developed in the future. The non-volatility of this storage means that the stored data is maintained regardless of whether power is being supplied to computer 201 and/or directly to persistent storage 213. Persistent storage 213 may be a read only memory (ROM), but typically at least a portion of the persistent storage allows writing of data, deletion of data and re-writing of data. Some familiar forms of persistent storage include magnetic disks and solid state storage devices. Operating system 222 may take several forms, such as various known proprietary operating systems or open source Portable Operating System Interface type operating systems that employ a kernel. The code included in ICSB framework and system 300 typically includes at least some of the computer code involved in performing the inventive methods.

Peripheral device set 214 includes the set of peripheral devices of computer 201. Data communication connections between the peripheral devices and the other components of computer 201 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 223 may include components such as a display screen, speaker, microphone, wearable devices (such as goggles and smart watches), keyboard, mouse, printer, touchpad, game controllers, and haptic devices. Storage 224 is external storage, such as an external hard drive, or insertable storage, such as an SD card. Storage 224 may be persistent and/or volatile. In some embodiments, storage 224 may take the form of a quantum computing storage device for storing data in the form of qubits. In embodiments where computer 201 is required to have a large amount of storage (for example, where computer 201 locally stores and manages a large database) then this storage may be provided by peripheral storage devices designed for storing very large amounts of data, such as a storage area network (SAN) that is shared by multiple, geographically distributed computers. IoT sensor set 225 is made up of sensors that can be used in Internet of Things applications. For example, one sensor may be a thermometer and another sensor may be a motion detector.

Network module 215 is the collection of computer software, hardware, and firmware that allows computer 201 to communicate with other computers through WAN 202. Network module 215 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 215 are performed on the same physical hardware device. In other embodiments (for example, embodiments that utilize software-defined networking (SDN)), the control functions and the forwarding functions of network module 215 are performed on physically separate devices, such that the control functions manage several different network hardware devices. Computer readable program instructions for performing the inventive methods can typically be downloaded to computer 201 from an external computer or external storage device through a network adapter card or network interface included in network module 215.

WAN 202 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 203 is any computer system that is used and controlled by an end user (for example, a customer of an enterprise that operates computer 201), and may take any of the forms discussed above in connection with computer 201. EUD 203 typically receives helpful and useful data from the operations of computer 201. For example, in a hypothetical case where computer 201 is designed to provide a recommendation to an end user, this recommendation would typically be communicated from network module 215 of computer 201 through WAN 202 to EUD 203. In this way, EUD 203 can display, or otherwise present, the recommendation to an end user. In some embodiments, EUD 203 may be a client device, such as thin client, heavy client, mainframe computer, desktop computer and so on.

Remote server 204 is any computer system that serves at least some data and/or functionality to computer 201. Remote server 204 may be controlled and used by the same entity that operates computer 201. Remote server 204 represents the machine(s) that collect and store helpful and useful data for use by other computers, such as computer 201. For example, in a hypothetical case where computer 201 is designed and programmed to provide a recommendation based on historical data, then this historical data may be provided to computer 201 from remote database 230 of remote server 204.

Public cloud 205 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 205 is performed by the computer hardware and/or software of cloud orchestration module 241. The computing resources provided by public cloud 205 are typically implemented by virtual computing environments that run on various computers making up the computers of host physical machine set 242, which is the universe of physical computers in and/or available to public cloud 205. The virtual computing environments (VCEs) typically take the form of virtual machines from virtual machine set 243 and/or containers from container set 244. It is understood that these VCEs may be stored as images and may be transferred among and between the various physical machine hosts, either as images or after instantiation of the VCE. Cloud orchestration module 241 manages the transfer and storage of images, deploys new instantiations of VCEs and manages active instantiations of VCE deployments. Gateway 240 is the collection of computer software, hardware, and firmware that allows public cloud 205 to communicate through WAN 202.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 206 is similar to public cloud 205, except that the computing resources are only available for use by a single enterprise. While private cloud 206 is depicted as being in communication with WAN 202, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 205 and private cloud 206 are both part of a larger hybrid cloud.

As shown in FIG. 2, one or more of the computing devices, e.g., computer 201 or remote server 204, may be specifically configured to implement a ICSB framework and system 300. The configuring of the computing device may comprise the providing of application specific hardware, firmware, or the like to facilitate the performance of the operations and generation of the outputs described herein with regard to the illustrative embodiments. The configuring of the computing device may also, or alternatively, comprise the providing of software applications stored in one or more storage devices and loaded into memory of a computing device, such as computing device 201 or remote server 204, for causing one or more hardware processors of the computing device to execute the software applications that configure the processors to perform the operations and generate the outputs described herein with regard to the illustrative embodiments. Moreover, any combination of application specific hardware, firmware, software applications executed on hardware, or the like, may be used without departing from the spirit and scope of the illustrative embodiments.

It should be appreciated that once the computing device is configured in one of these ways, the computing device becomes a specialized computing device specifically configured to implement the mechanisms of the illustrative embodiments and is not a general purpose computing device. Moreover, as described hereafter, the implementation of the mechanisms of the illustrative embodiments improves the functionality of the computing device and provides a useful and concrete result that facilitates machine learning of command line interface functionality for input patterns of commands and options and simulating the command line interface for various operating systems dynamically based on user requests and user specified commands and options.

It should be appreciated that while FIG. 2 illustrates an example embodiment in which the ICSB framework and system 300 is implemented via a single computing system, the illustrative embodiments are not limited to such. Rather, in other illustrative embodiments, the components of the ICSB framework and system 300 and their operations/functionality may be distributed across multiple computing devices or systems, such as multiple server computing devices, without departing from the spirit and scope of the present invention. FIG. 2 is merely an example demonstrating one possible implementation via an example computing system.

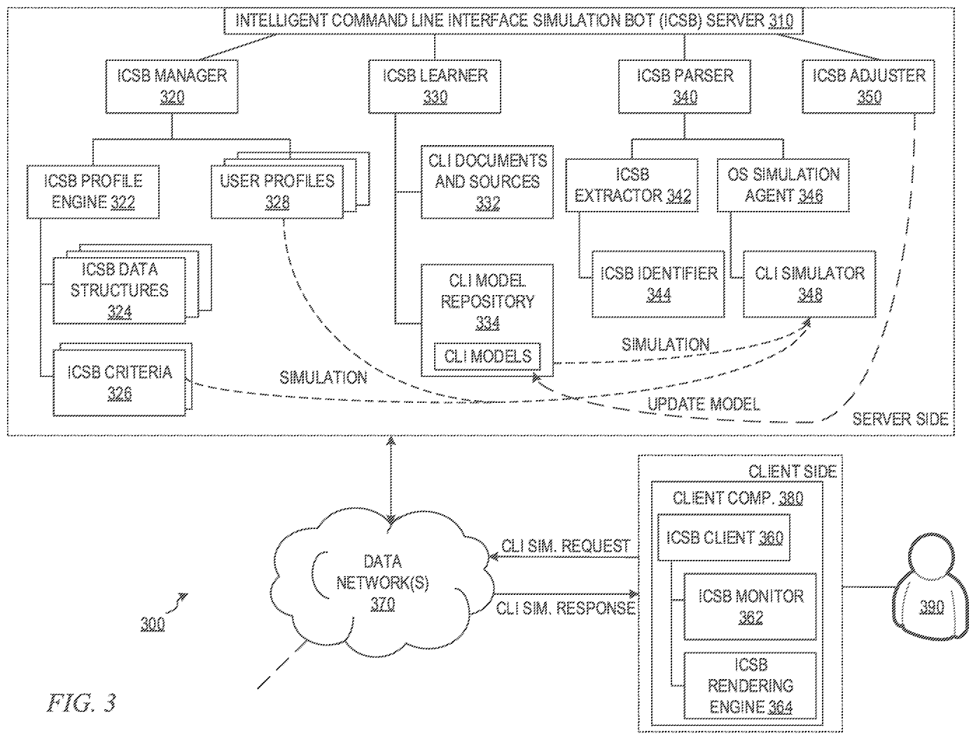

FIG. 3 is an example diagram of an intelligent command line interface simulation bot (ICSB) framework and system in accordance with one illustrative embodiment. The operational components shown in FIG. 2 may be implemented as dedicated computer hardware components, computer software executing on computer hardware which is then configured to perform the specific computer operations attributed to that component, or any combination of dedicated computer hardware and computer software configured computer hardware. It should be appreciated that these operational components perform the attributed operations automatically, without human intervention, even though inputs may be provided by human beings, e.g., requests for simulation of command line interfaces of operating systems, commands and options to be simulated via the command line interface simulation, and the like, and the resulting output may aid human beings, e.g., simulating a command line interface response to a user entered command and options. The invention is specifically directed to the automatically operating computer components directed to improving the way that users may experience operating systems and command line interfaces of these operating systems without having to explicitly have the hardware and install/configure the operating systems of interest are performed, and providing a specific solution that implements machine learning of command line interfaces and their responses to specific commands and combinations of commands with options, and subsequent simulation of these command line interfaces for user specified commands and options. These operations cannot be practically performed by human beings as a mental process and are not directed to organizing any human activity.

As shown in FIG. 3, the Intelligent Command Line Interface (CLI) Simulation Bot (ICSB) framework and system 300 includes an ICSB server 310 and an ICSB client 360. The ICSB server 310 may comprise components implemented on one or more computing systems/devices accessible via one or more data networks 370 by client computing systems that implement the ICSB client 360. The ICSB client 360, which may be an application or plug-in to a browser application executing on the client computing device 380, includes an ICSB monitor 362 and ICSB rendering engine 364. The ICSB client 360 comprises logic that informs the ICSB server 310 that the user 390 of the client computing device 380 is wanting to invoke the CLI simulation of the ICSB server 310.

The ICSB server 310 includes an ICSB manager 320, and ICSB learner 330, an ICSB parser 340, and ICSB adjuster 350. The ICSB manager 320 further includes an ICSB profile engine 322 and user profiles storage 328, where the ICSB profile engine 322 operates in conjunction with ICSB data structures 324 and ICSB criteria storage 326. The ICSB profile engine 322 comprises logic for creating, maintaining, updating, and removing ICSB data structures 324 and ICSB criteria 326, as well as user profiles in user profiles storage 328. The ICSB manager 320 operates dynamically and automatically in response to user inputs from ICSB client 360 and results of CLI simulations by the ICSB server 310 that are generated and returned to the ICSB client 360. The ICSB data structures 324 store various operating system, CLI, and user features that are dynamically and automatically populated during a CLI simulation session between the ICSB client 360 and the ICSB server 310.

The ICSB criteria 326 store the requirements for supporting CLI simulation, such as the operating systems that are to be supported, the scope of the CLI simulation, e.g., how many and what commands and options to simulate, default environment variables (e.g., local, IP address, CPU/GPU/Memory, storage type and size, tools, etc.), and the like. The ISCB criteria 326 may be modified by administrators or other authorized personnel that wish to make changes to the CLI simulation provided by the ICSB server 310, e.g., when a new operating system command line interface is to be supported, this information for the new operating system command line interface may be added to the ICSB criteria 326.

The user profiles 328 may store information, similar to the ICSB criteria 326, which are specific to the particular user. For example, the user profiles 328 may store information about particular operating systems that the user wishes to simulate via the ICSB server 310, what subset of commands and options the user is wanting to simulate, as well as CLI simulation history information which may be used and/or viewed for educational, training, and certification purposes, for example. The user profile 328 may specify additional criteria for CLI simulations, e.g., different operating system command line interfaces to simulate that may be different from the ICSB criteria 326. For example, if the user wishes to simulate a different operating system command line interface than is supported by the ICSB criteria 326, then the additional operating system CLI requirement may be specified in the user profile 328 and the ICSB learner 330 may operate to automatically learn the CLI model for that user requested operating system CLI.

The ICSB learner 330 comprises machine learning logic to automatically learn associations of patterns of input CLI commands and options with patterns of CLI outputs from various CLI data sources and documents 332 to generate one or more CLI models that are stored in the CLI model repository 334. The ICSB learner 330 may ingest structured and unstructured data, e.g., electronic documents from various sources, such as Wikipedia, operating system user documentation, man pages (“man” is a command that returns a definition of subsequently specified command, e.g., “man grep” gives the definition of the command “grep”), design documents, red books, support hub web pages, and the like. For example, as shown in FIG. 1, one source of documentation may include a structured table of options supported by various operating system command lines. The table shown in FIG. 1 indicates the options, e.g., “-m”, and whether an operating system, AIX®, Linus (GNU), or Solaris, supports that option, where a blank entry indicates the option is supported and a “N” entry indicates it is not supported.

The ICSB learner 330 ingests the various sources of data and learns, through machine learning processing of the structured and unstructured data, the commands and options supported by the various operating systems and the corresponding results that the command line interface interpreters will return as a result of those commands and options. That is, patterns of commands and options may be extracted from the ingested data and patterns of command line interface interpreter results will also be extracted and mapped to the corresponding commands and options. In this way, the ICSB learner 330 learns a CLI model that associates patterns of commands and options with patterns of CLI results. The ICSB learner 330 may perform such operations for each individual operating system CLI that is to be modeled. Each CLI model that is generated through this machine learning by the ICSB learner 330 may be stored in the CLI model repository 334. The ICSB learner 330 further provides logic for retrieving stored CLI models from the CLI model repository 334 on-demand for use in performing CLI simulations by the CLI simulator 348.

The ICSB parser 340 comprises logic for parsing user requests received via the ICSB monitor 362 of the ICSB client 360, e.g., via an AI chatbot such as Chat GPT or other natural language text based interface, and the ICSB server 310. The ICSB parser 340 is able to parse and extract features from the user 390 input to the ICSB client 360 where these extracted features correspond to one or more of the features present in the ICSB data structure 324, as discussed previously. For example, the features may include user, operating system (OS) and CLI feature data similar to that maintained in the ICSB data structure 324. As mentioned above, the ICSB data structure 324 includes features such as user identifier (UserID), operating system name (OSName), configuration information for the operating system and user identifier (Configuration[OSName][UserID]), CLI list of operating systems invoked by the user (CLIList[OSName]), a CLI log for the operating system and user identifier (CLILog[OSName][UserID]) which maintains a log for each operating system as to the commands entered by the user corresponding to the user ID, a user command (UserCMD) specifying the latest command entered by the user into the simulated CLI, a command options (CMDOptions) specifying the latest command options entered by the user into the simulated CLI, a command output generated by the simulated CLI for the latest entered command (CMDOutput), and an error state (Error State) specifying whether or not an error occurred in the CLI when processing the entered command, e.g., the CLI does not support a particular command or option. Some of these features may be obtained from results of the CLI simulation rather than directly from the user input and may be populated by the ICSB server based on the ICSB server operations rather than specifically parsing and extraction of the features from user input.

As an example, the ICSB server 310 may implement an AI chatbot with the mechanisms of the illustrative embodiments augmenting and expanding the AI chatbot capabilities to specifically be able to learn command line interface command/option mappings with command line interface outputs or results, and use the resulting command line interface (CLI) models to simulate a user requested CLI based on user specified files and commands/options. The ICSB parser 340 parses such requests from users 390 received via their ICSB clients 360, and identified as requests to simulate OS and command line by the ICSB monitor 362, and invokes ICSB extractor 342 to extract features from the user requests including ICSB identifiers 344 that identify specific operating system command line interfaces, command line commands and options, and other features of the ICSB data structure. For example, the ICSB extractor 342 may identify features in the user input received from the ICSB client 360 including the user identifier, OS name, configuration information for the OS, a user command, a command options, and the like.

The ICSB parser 340 further operates to invoke an operating system (OS) simulation agent 346 that operates to generate a simulation of an operating system environment specified by the user 390 in the user request from the ICSB client 360, based on the extracted features from the ICSB extractor 342. In response to the user 390 of the ICSB client 360 entering a command to simulate, the OS simulation agent 346 invokes the CLI simulator 348 to simulate the command line interface interpreter based on a CLI model from the CLI model repository 334 corresponding to the OS being simulated. The simulation may be further configured by the ICSB criteria 326 and user profiles 328, for example, and features corresponding to the CLI simulation and user inputs to the CLI simulation may be used to update the ICSB data structures 324 via the ICSB manager 320 and ICSB profile engine 322.

The CLI model implemented in the CLI simulator 348 maps feature patterns of command inputs to corresponding CLI responses or outputs. Thus, the CLI simulator 348 simulates the response of the CLI interpreter in response to the command and options if any, and returns a result. In some cases, the command and options may not be supported by the particular OS and CLI interpreter, in which case the CLI simulator 348 may return a result indicating that the particular command and/or option(s) are not supported and providing additional assistance as to which commands and/or option(s) are supported, e.g., a listing of supported options. The ICSB parser 340 then returns the result of the command/option, as generated by the CLI simulation, to the ICSB client 360 which presents the result to the user of the client computing device via the ICSB rendering engine 364.

For example, a user 390 may input via their ICSB client 360, a natural language request of a type “In Redhat Linux” to request that the ICSB service 310 simulate Redhat® (a registered trademark of Red Hat, Inc.) Linux® (a registered trademark of Linus Torvalds) and may input a sample file, e.g., “test.txt”. In the examples provided herein, the “test.txt” file is a text file having the first 6 lines being of the type “Apple-1” through “Apple-6” and the following 6 lines being “Peach-1” through “Peach-6”, as will be shown in subsequently reference figures. The user 390 may further input the command line interface command and option that the user 390 wishes to simulate, e.g., “grep -m 1 Apple test.txt” which obtains the first line of the test.txt file what includes the character string “Apple”. The ICSB server 310 will simulate the CLI and provide the simulated result of “Apple-1” in this example. However, at no point in this simulation is there any requirement that the user install and configure the requested operating system(s) or provide equipment to run the requested operating system(s). In fact, the user 390 may simulate operating system(s) and their command line interfaces that do not even exist on the user's client computing device 380.

It should be appreciated that the user 390 of the ICSB client 360 may submit requests to dynamically switch the operating system and command line interface of the simulation at any point, and even switch back and forth between various operating systems on-the-fly. The ICSB server 310 processes such requests and automatically and dynamically changes the OS being simulated by the OS simulation agent 346 and corresponding CLI simulation performed by the CLI simulator 348 based on the corresponding CLI model form the CLI model repository 334 as needed. This is done with little if any perceived delay as there is no requirement to install and configure an actual operating system on actual computer hardware.

The results of the CLI simulation are returned by the ICSB server 310 to the ICSB client 360 as they are generated in response to user 390 entered commands into the ICSB rendering engine 364. The ICSB rendering engine 364 emulates a command line interface such that the user 390 perceives that they are interacting with an actual command line interface of an actual operating system, when in fact they are interacting with a simulation. The ICSB rendering engine 364 receives the CLI simulation responses from the ICSB server 310 and renders them in the simulated command line interface displayed to the user 390. The user 390 may enter commands and options into the simulated command line interface, which are then sent as CLI simulation requests to the ICSB server 310 which then uses the CLI simulation and corresponding CLI model to simulate the results of the CLI interpreter for the user's entered command and provide those results as a CLI simulation response back to the ICSB client 360.

In some cases, the user 390 may feel that the result generated by the CLI simulator 348 and provided to the ICSB client 360 is not accurate. In such a case, the user 390 may provide user feedback via user interface elements provided by the ICSB rendering engine 364 or subsequent natural language input to the AI chatbot interface, for example. The user feedback may then be processed by the ICSB adjuster 350 to adjust the CLI model in the CLI model repository 334. That is, the ICSB adjuster 350 may utilize the user feedback as a ground truth for retraining the CLI model with regard to the user entered command. In this retraining, weights of nodes of the CLI model or mappings between input feature patterns and CLI simulated results may be updated to reduce the error in the CLI simulated results.

Thus, as noted above, the illustrative embodiments provide improved computing tools and improved computing tool operations/functionality to simulate command line interfaces such that users are not required to have access to necessary hardware and software to install and configure operating systems in order to utilize the command line interfaces of those operating systems. This is of significant benefit to a number of different educational, training, certification, research, and product development industries. With the mechanisms of the illustrative embodiments, users no longer are required to expend resources in obtaining the necessary hardware to run all the various operating systems that they wish to utilize, and are no longer required to expend the time and effort to install and configure the various operating systems they wish to utilize, in order to achieve their educational, training, certification, research, and product development goals.

For example, without the mechanisms of the illustrative embodiments, a user would have to ensure that they have the requisite hardware capacity to handle the most resource utilization intensive operating system, must then obtain licenses for each of the operating systems that they wish to utilize, must then obtain the software for the operating systems, and then must install and configure each operating system separately, and sequentially, as the user wishes to utilize the various operating systems. This is an extremely resource intensive and time intensive operation, as it may take hours to switch between operating systems by having to uninstall one operating system, install a new operating system, and configure the new operating system for the computing environment, in order to able to utilize the new operating system, and this would need to be done each time the user wishes to utilize a different operating system and its command line interface.

The mechanisms of the illustrative embodiments virtualize the operating system and command line interface through AI machine learning tools such that the user need not have any new or additional hardware or software apart from the installation of a plug-in to their existing web browser application on their client device, as the operating system and command line interface are simulated at the ICSB server 310 and CLI simulated results returned to the ICSB client 360. This further allows for automatic and dynamic switching between operating systems on-the-fly.

In some illustrative embodiments, the ICSB client 360 may facilitate multiple windows representing different operating system command line interface simulations, being presented at substantially a same time so that comparisons of the operation of the CLIs between different operating systems on the same or different commands and options may be made visually to the user 390. For example, one window may execute the simulation of an IBM AIX® operating system command line while another window may execute the simulation of a Solaris operating system command line, with regard to the same or different commands and options. Such multiple operating system displays may be instigated in response to a user switching to a new operating system through a user request, in which case a new window to depict the new operating system and command line interface simulation results may be automatically spawned by the ICSB rendering engine 364 on the client computing device 380. This is especially useful for educational, training, and certification purposes.

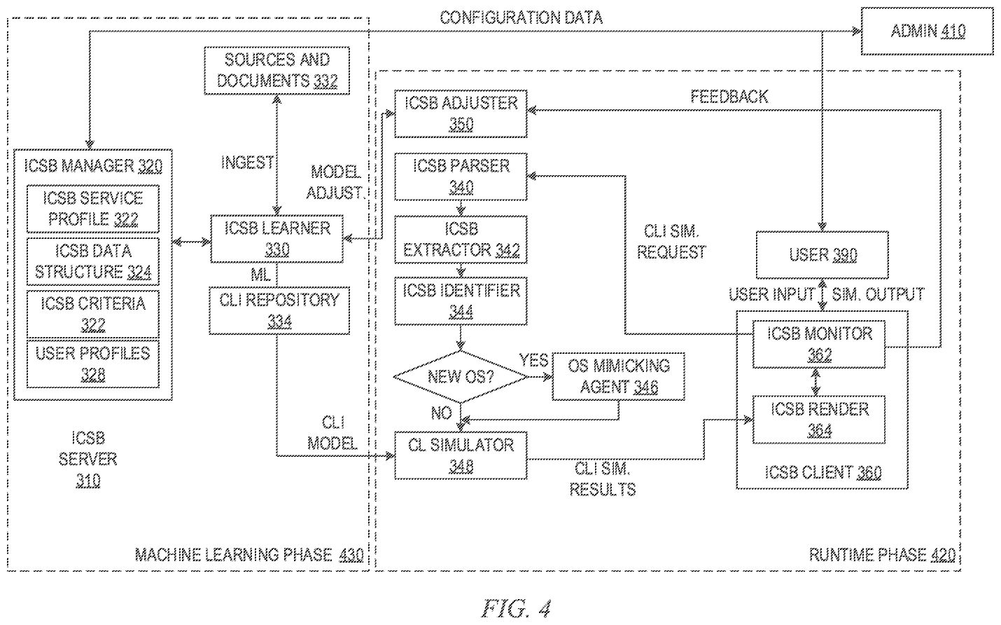

FIG. 4 is an example flow diagram illustrating an example operation of the ICSB framework and system in accordance with one illustrative embodiment. It should be appreciated that the operations outlined in FIG. 4 are specifically performed automatically by an improved computer tool of the illustrative embodiments and are not intended to be, and cannot practically be, performed by human beings either as mental processes or by organizing human activity. To the contrary, while human beings may, in some cases, initiate the performance of the operations set forth in FIG. 4, and may, in some cases, make use of the results generated as a consequence of the operations set forth in FIG. 4, the operations in FIG. 4 themselves are specifically performed by the improved computing tool in an automated manner.

As shown in FIG. 4, a user 390 installs a ICSB client 360 on their client computing device and may then log into the ICSB server 310, which may provide an AI chatbot or other natural language based AI computing system which is augmented to include the tools and functionality of the illustrative embodiments for simulating operating system command line interfaces. Requests to simulate an OS and command line of the OS will be identified by the ICSB monitor 362 of the ICSB client 360. The ICSB monitor 362 will send user requests for OS and command line simulation to the ICSB parser 340. The ICSB parser 340 parses the user request and invokes the ICSB extractor 342 to extract features from the user request that are indicative of ICSB data structure features, e.g., OS name, user identifier, command name, command option, etc. The ICSB identifier 344 identifies these features in the extracted features and updates the ICSB data structure 324 via the ICSB manager 320.

Based on the extracted and identified features, a determination is made as to whether the user is requesting to use a new operating system for command line interface simulation. If so, the operating system simulation agent 346 is invoked to simulate the operating system environment. Thereafter, or if the operating system is not a new operating system, the command line interface simulator 348 is invoked to simulate the command line interface on the user input command in the user request. This is represented as the “runtime” or simulation phase of operation 420.

The command line interface simulator 348 operates based on CLI models stored in the CLI repository 334, as well as other parameters that are used to configure the CLI simulations, e.g., user profile data 328 and ICSB criteria 326. The user inputs and simulation results are used to populate fields of the ICSB data structure 324 over time as the user interacts with the ICSB server 310 via the ICSB client 360. During a machine learning phase 430 of operation, the ICSB server 310 invokes a ICSB learner 330 to ingest structured and non-structured documents and data from data sources 332 to learn the CLI models for various operating systems and commands/options of the command line interfaces of those operating systems, as specified by the user profiles 328 and ICSB criteria 326. The ICSB service profile 322 and user profiles 328 are configuration files, such as in plain text or XML format, for example. The ICSB service profile 322 (controlled and edited by an administrator through an ICSB manager 320) may include high level configuration parameters and settings for all of the ICSB users. The ICSB service profile 322 may include ICSB data structure and ICSB criteria. The administrator may add/remove/change the attributes of the ICSB data structure and criteria in the ICSB criteria. For example, the default colors for background of a simulated Linux® and AIX® operating system to black and white, respectively, and an administrator may set the colors to red, for example, for all error message by default.

Similarly, the user profile 328 includes personal characteristics and customized settings. For example, a first user, e.g., USER-1, can add/save a new simulated operating system, e.g., Microsoft Windows 11, and CLI documents and sources 332 related to Microsoft Windows 11 in the user profile. Moreover, the user can set background colors of a simulated operating system, Linux, to a white color for readability. Any personal characteristics and customized settings specific to the user may be set in the user profile 328.

The CLI models for the various operating systems and command line interfaces are stored in the CLI repository 334 for retrieval by the CLI simulator 348 to generate CLI simulated results which are then provided back to the ICSB rendering engine 364 for rendering the graphical/textual representation of the simulated command line interface for the requested operating system and specifically the simulated results of the user entered command and options that would be generated by the actual CLI of the actual operating system.

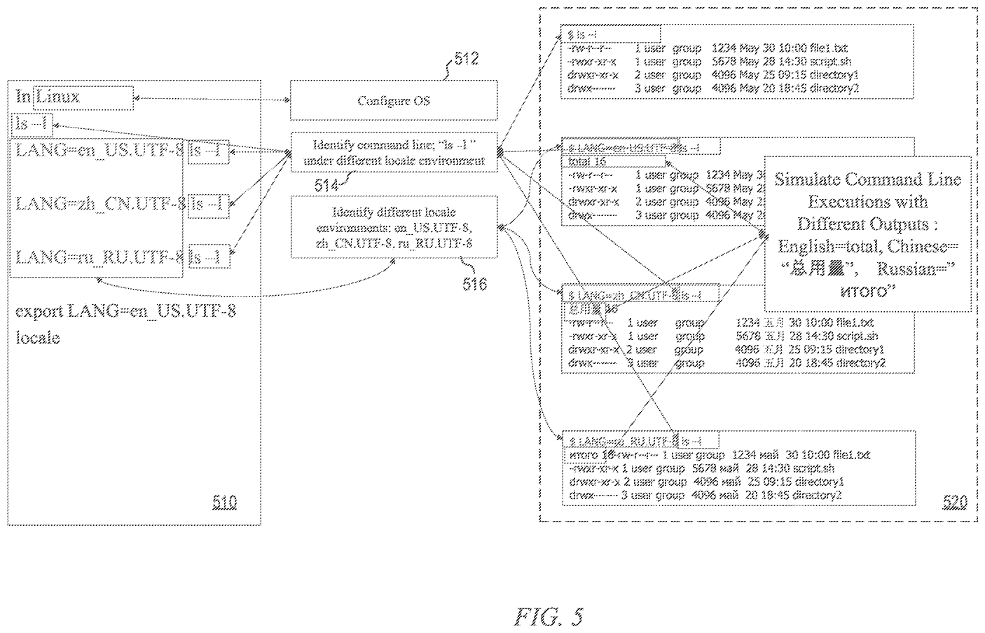

The mechanisms of the illustrative embodiments may be utilized in many different ways to facilitate education, training, certification, research, and product development. One benefit of the illustrative embodiments is the ability to identify quickly, and with little expenditure of resources and time, the differences between command line interfaces of various operating systems as well as differences in CLI results generated for different commands and options in one or more command line interfaces. FIG. 5 is an example diagram illustrating a simulation of a command in a simulated operating system CLI in accordance with one illustrative embodiment. In the depicted example, the user request or user input is shown as element 510 which includes a specification of the particular operating system command line to simulate 512, which in the depicted example is Linux. The user request further specifies the list file command “ls −1”, and further lists the “ls −1” command with various options for output languages (or locales), e.g., English (en_US.UTF-8), Chinese (zh_CN.UTF-8), and Russian (ru_RU.UTF-8). As can be seen in element 520, for each of these options, there is a different output in which the word “total” is presented is the corresponding locale language. Such outputs 520 may be quickly and easily obtained using the mechanisms of the illustrative embodiments with the command input 510 shown using CLI simulation which simulates different CLI responses to the entered user commands.

Thus, it can be seen from FIG. 5 that the illustrative embodiments may operate to demonstrate that the same CLI with the same options in the same OS may give different outputs due to execution under different languages/locale settings. In a real operation system, in order to get similar demo results in this example, user has to install required language/locale packages (en_US.UTF-8, zh_CN.UTF-8, and ru_RU.UTF-8, in this example), and such installing of the different locale packages may need root privilege, which is difficult, inconvenient, and time consuming to install and configure multilingual packages in a real system. In the illustrative embodiments, however, different locale environments can be mimicked, which is very useful in education, new features design, and customer support applications.

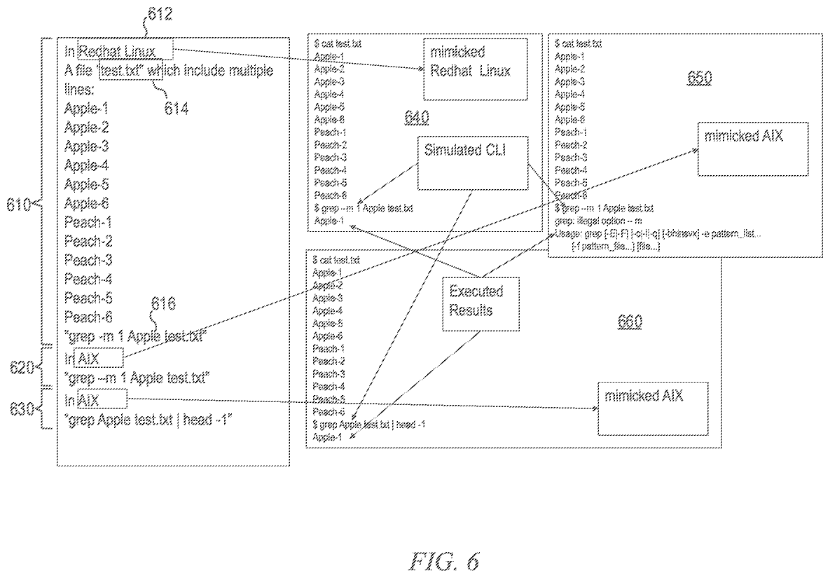

FIG. 6 is an example diagram illustrating an example simulated CLI output or result generated based on an input command to the ICSB framework and system in accordance with one illustrative embodiment. The simulated CLI output or result may be presented to the user via the ICSB rendering engine which may render the screens 640-660 shown in FIG. 6, for example. These screens simulate the actual command line interfaces that one would see if they had installed and configured an instance of an operating system and its command line interface, but in actuality these screens 640-660 are simulated command line interfaces that present the simulated CLI responses generated by the ICSB server based on user requests from the ICSB client.

As shown in FIG. 6, a user request or input 610 includes a user request 612 to simulate the Redhat Linux® operating system command line interface, followed by a specification of a “test.txt” file 614 on which the commands are to be run, where the example “test.txt” file has the first 6 lines being “Apple-1” through “Apple-6” and the next 6 lines being “Peach-i” through “Peach-6.” The user request 610 further specifies a command 616 of “grep -m 1 Apple test.txt”, where “grep” is the command, “-m 1” is an option for the command, “Apple” is the character string to be searched for, and “test.txt” is the file upon which the command 616 is to be executed. This grep command 616 is intended to return the first line of the test.txt file that has the character string “Apple” in it.

The user session further includes subsequent user requests 620 and 630. These user commands include a command to change the operating system from Redhat Linux® to AIX. In addition, these user requests specify similar grep commands. In the case of user request 620, the results of the command will return an “illegal option” CLI simulated response as the option “-m” is not supported by AIX® as learned by the mechanisms of the illustrative embodiments and represented in the CLI model. In the case of the user request 630, the user inputs a different form of the grep command with appropriate options, resulting in a simulated CLI response. The simulated CLI responses generated by the mechanisms of the illustrative embodiments are shown in screens 640, 650, and 660, respectively. A shown, for the first user request 610, the CLI simulated response in screen 640 is “Apple-1”, as is the case for the third user request 630, shown in screen 660. The output on screen 650 indicates the illegal option and provides option alternatives for the command.

Thus, as shown in FIG. 6, the illustrative embodiments may operate to demonstrate that the same CLI with the same options may return different outputs in different operating systems. Without the illustrative embodiments, in order to show the different results in different OS, the user would have to install and set different systems with different operating systems in different hardware. Therefore, it is not easy and convenient to obtain the proper hardware with the right OS for normal users. With the illustrative embodiments, however, a user can easily set the mimicked operating systems for comparing, testing, verify the CLI with different options under different operating systems. Again, this is very useful in education, new features design, and customer support.

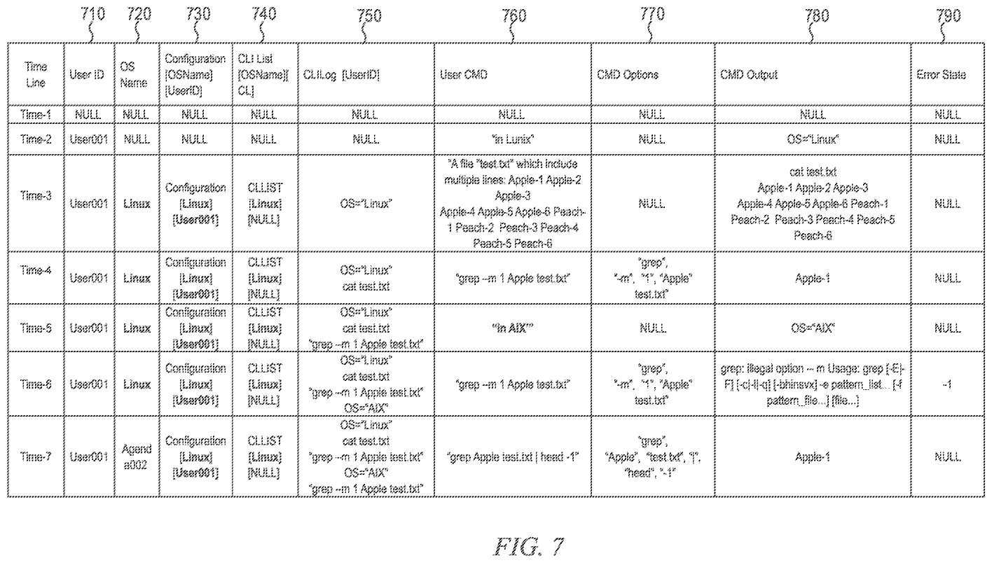

As noted above, the ICSB server maintains information about the user session with the ICSB server over time in an ICSB data structure. FIG. 7 is an example diagram of a ICSB data structure as it evolves over a period of time of a ICSB session with a user, i.e., a session between the ICSB server and the ICSB client, in accordance with one illustrative embodiment. In the depiction of FIG. 7, the time intervals “Time-1” to “Time-7” are shown on the left hand side, while the various ICSB data structure fields 710—for the various ICSB features are shown across the top of the diagram as separate columns. The cells of the ICSB data structure comprise the ICSB server captured data for the various features at the various time intervals. A value of “Null” indicates that this feature has not yet been set during the ICSB session.

As shown in FIG. 7, initially, when the ICSB session is established, none of the features are populated (Time-1). Thereafter, at Time-2, a user may submit a user request, such as “In Linux” (760), where the user request specifies the user ID of the user (710), the user entered command “In Linux” (760) and based on the command (760) a corresponding CLI simulated output is generated (780), e.g., “OS=Linux”, is identified. At a subsequent time interval (Time-3), the user enters a command specifying the test.txt file, as shown (760). The OS name (720) is updated to reflect that the operating system is Linux, the Configuration information (730) is updated to reflect the configuration for Linux® and for the user (710), the CLI list is updated based on the OS of Linux® (740), the CLI Log (750) is updated to reflect the CLI simulated response from the previous time interval, i.e., “OS=Linux”. The command output from the CLI simulated response is shown in field 780 which includes the contents of the test.txt file.

In a subsequent time interval (Time-4) the CLI Log (750) is again updated with the CLI simulated response (780) from the previous time interval, a new user command is input (760), e.g., “grep -m 1 Apple test.txt”, and the command options for this command are identified and stored in the command options field (770), e.g., “grep”, “-m”, “1”, “Apple”, “test.txt”. The CLI simulated response is stored in the command output field (780), e.g., “Apple-1”.

This process continues with each subsequent time interval and each user request/command entered by the user, e.g., “in AIX” in time interval Time-5, “grep -m 1 Apple test.txt” in time interval Time-6, and “grep Apple test.txt| head-1” in time interval Time-7, as shown in FIG. 7. Thus, the ICSB data structure is dynamically and automatically updated over time as the session between the ICSB server and ICSB client continues. The ICSB data structure is used to facilitate the presentation of simulated CLI results to the ICSB client as well as log the ICSB session.

As noted above, the ICSB data structure and contained attributes are changed dynamically based on user requests over time. Thus, using the example shown in FIG. 7, assume that at a first time, all parameters are NULL. Thereafter the following dynamic modifications are made over time for time points Time-2 through Time-7:
Time-2: User001 in ICSB client typed “in Linux”. As part of user request, the value of “User CMD” is parsed and the value of CMD is identified by ICSB server. CMD output is OS=Linux
Time-3: related variable assignment operations involved in ICSB Server side. The “OS NAME”=Linux. The simulated OS is initialized and/or changed to OS=“Linux.” A next user request is received as “A file “test.txt” which includes multiple lines: Apple-1 Apple-2 Apple-3 Apple-4 Apple-5 Apple-6 Peach-1 Peach-2 Peach-3 Peach-4 Peach-5 Peach-6”. The CMD output is simulated as “cat test.txt Apple-1 Apple-2 Apple-3 Apple-4 Apple-5 Apple-6 Peach-1 Peach-2 Peach-3 Peach-4 Peach-5 Peach-6.”
Time-4: the ICSB Server receives a new user request “grep -m 1 Apple test.txt” and the assignment: “CMD Options”=(“grep”, “-m”, “1”, “Apple” test.txt”). According to learned knowledge, the simulated CMD output=“Apple” which is returned to the ICSB Client as a simulated output result.
Time-5: the ICSB server receives a new request “in AIX”, then changes the OS system from Linux® to “OS NAME”=“AIX”.
Time 6: the ICSB server receives a new user request “grep -m 1 Apple test.txt” and then the assignment: “CMD Options”=(“grep”, “-m”, “1”, “Apple” test.txt”). Then, according to the learned knowledge, the simulated CMD output=“grep: illegal option - -m Usage: grep [-E|-F][-c|-1|-q][-bhinsvx]-e pattern_list . . . [-f pattern_file . . . ][file . . . ]” and is returned to ICSB Client as a simulated output result. The error state is then updated Error State=−1 (which means an error was found).
Time 7: the ICSB Server receives a new user request “grep Apple test.txt|head -1” and then the assignment: “CMD Options”=(“grep”, “Apple”, “test.txt”, “|”, “head”, “−1”). Then, according to the learned knowledge, the simulated CMD output=“Apple-1” and is returned to the ICSB Client as a simulated output result.

The description of the present invention has been presented for purposes of illustration and description, and is not intended to be exhaustive or limited to the invention in the form disclosed. Many modifications and variations will be apparent to those of ordinary skill in the art without departing from the scope and spirit of the described embodiments. The embodiment was chosen and described in order to best explain the principles of the invention, the practical application, and to enable others of ordinary skill in the art to understand the invention for various embodiments with various modifications as are suited to the particular use contemplated. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, in a data processing system, for simulating operating systems, the method comprising:
training, for each operating system of one or more operating systems, a corresponding artificial intelligence (AI) computer model that learns, by way of machine learning training, patterns of input features of inputs to the operating system and corresponding responses from the operating system;
receiving, from a requestor computing device, a request to simulate a requested operating system;
receiving, from the requestor computing device, a simulation input whose processing by the requested operating system is to be simulated;
retrieving an AI computer model corresponding to the requested operating system;
executing the retrieved AI computer model on the simulation input to simulate processing, by the request operating system, of the simulation input to generate a simulated response; and
returning the simulated response to the requestor computing device as a simulated output of the requested operating system responsive to the input.

2. The method of claim 1, wherein the corresponding AI computer model is a command line interface (CLI) computer model that maps patterns of input features of commands input to a CLI of the operating system with corresponding CLI responses.

3. The method of claim 1, wherein the request is a request to simulate a CLI of the requested operating system and wherein the input whose processing by the requested operating system is to be simulated is a command to the CLI.

4. The method of claim 1, wherein the simulation input is a command for a command line interface (CLI) of the requested operating system, and wherein the simulated output is a simulated CLI response generated by simulating the requested operating system based on the retrieved AI computer model.

5. The method of claim 4, wherein returning the simulated response to the requestor computing device as a simulated output of the requested operating system responsive to the input comprising returning the simulated CLI response in a simulated user interface mimicking a command line interface of the requested operating system.

6. The method of claim 1, wherein the patterns of input features comprise patterns of operating system commands input to a command line interface of the operating system, and corresponding options for those operating system commands.

7. The method of claim 1, wherein:
the one or more operating systems comprises a plurality of operating systems,
training the AI computer model comprises training a separate AI computer model for each different operating system in the plurality of operating systems, and
each of the AI computer models are trained to simulate a same set of command line interface commands but with regard to a corresponding operating system, in the plurality of operating systems.

8. The method of claim 1, wherein the AI computer model is trained based on a machine learning processing of a training data set comprising a set of command line interface commands, options for the command line interface commands, and expected command line interface outputs for the commands and options based on an ingested corpus of source documents comprising operating system design documents, support hubs, and man pages.

9. The method of claim 1, wherein the request is a natural language request submitted via a chatbot interface and specifies the requested operating system and the simulating input whose processing by the requested operating system is to be simulated.

10. The method of claim 1, further comprising:
receiving a user profile specifying a subset of operating systems to simulate, wherein the training of the corresponding AI computer model is performed for each of the operating systems specifies in the user profile.

11. The method of claim 10, wherein the user profile further specifies, for the subset of operating systems, a scope of commands that are to be learned by the training of the corresponding AI computer models, and a default set of environment variables to use in simulating the subset of operating systems.

12. The method of claim 1, further comprising:
receiving user feedback information in response to the simulated response indicating whether the simulated response is correct or incorrect; and
updating a training of the retrieved AI computer model based on the user feedback information.

13. A computer program product comprising a computer readable storage medium having a computer readable program stored therein, wherein the computer readable program, when executed in a data processing system, causes the data processing system to simulate operating systems at least by:
training, for each operating system of one or more operating systems, a corresponding artificial intelligence (AI) computer model that learns, by way of machine learning training, patterns of input features of inputs to the operating system and corresponding responses from the operating system;
receiving, from a requestor computing device, a request to simulate a requested operating system;
receiving, from the requestor computing device, a simulation input whose processing by the requested operating system is to be simulated;
retrieving an AI computer model corresponding to the requested operating system;
executing the retrieved AI computer model on the simulation input to simulate processing, by the request operating system, of the simulation input to generate a simulated response; and
returning the simulated response to the requestor computing device as a simulated output of the requested operating system responsive to the input.

14. The computer program product of claim 13, wherein the corresponding AI computer model is a command line interface (CLI) computer model that maps patterns of input features of commands input to a CLI of the operating system with corresponding CLI responses.

15. The computer program product of claim 13, wherein the request is a request to simulate a CLI of the requested operating system and wherein the input whose processing by the requested operating system is to be simulated is a command to the CLI.

16. The computer program product of claim 13, wherein the simulation input is a command for a command line interface (CLI) of the requested operating system, and wherein the simulated output is a simulated CLI response generated by simulating the requested operating system based on the retrieved AI computer model.

17. The computer program product of claim 16, wherein returning the simulated response to the requestor computing device as a simulated output of the requested operating system responsive to the input comprising returning the simulated CLI response in a simulated user interface mimicking a command line interface of the requested operating system.

18. The computer program product of claim 13, wherein the patterns of input features comprise patterns of operating system commands input to a command line interface of the operating system, and corresponding options for those operating system commands.

19. The computer program product of claim 13, wherein:
the one or more operating systems comprises a plurality of operating systems,
training the AI computer model comprises training a separate AI computer model for each different operating system in the plurality of operating systems, and
each of the AI computer models are trained to simulate a same set of command line interface commands but with regard to a corresponding operating system, in the plurality of operating systems.

20. An apparatus comprising:
at least one processor; and
at least one memory coupled to the at least one processor, wherein the at least one memory comprises instructions which, when executed by the at least one processor, cause the at least one processor to simulate operating systems at least by:
training, for each operating system of one or more operating systems, a corresponding artificial intelligence (AI) computer model that learns, by way of machine learning training, patterns of input features of inputs to the operating system and corresponding responses from the operating system;
receiving, from a requestor computing device, a request to simulate a requested operating system;
receiving, from the requestor computing device, a simulation input whose processing by the requested operating system is to be simulated;
retrieving an AI computer model corresponding to the requested operating system;
executing the retrieved AI computer model on the simulation input to simulate processing, by the request operating system, of the simulation input to generate a simulated response; and
returning the simulated response to the requestor computing device as a simulated output of the requested operating system responsive to the input.
